(19) United States
(12) Patent Application Publication
(10) Pub. No.: US 2010/0208531 A1
(43) Pub. Date: Aug. 19, 2010

(54) DATA READING CIRCUIT

(76) Inventor: Kotaro Watanabe, Chiba-shi (JP)

Correspondence Address: Brinks Hofer Gilson & Lione/Seiko Instruments Inc., P.O. Box 10395, Chicago, IL, 60611, US

(21) Appl. No.: 12/705,791

(22) Filed: Feb. 15, 2010

(30) Foreign Application Priority Data
Feb. 18, 2009 (JP) JP2009-035514

(51) Int. Cl. G11C 7/00; G11C 7/10

(52) U.S. Cl. 365/189.15; 365/189.05

(57) ABSTRACT

There is provided a data reading circuit which is low in current consumption. In a read period, a signal (φ2) is low, and hence an NMOS transistor (14) turns off. Accordingly, no current flows in the NMOS transistor (14). Further, data (D2) is high, and hence an output voltage of an inverter (23) becomes low, and an NMOS transistor (32) turns off. Accordingly, no current flows in the NMOS transistor (32). Further, in a PMOS transistor (31), a power supply voltage (VDD) is applied to a source and a drain thereof, and hence no current flows. As a result, no current flows in the data reading circuit during a read period after a data holding operation of a latch circuit (21) has been completed (after time (t4)), and hence the current consumption of the data reading circuit is reduced accordingly.

### RELATED APPLICATIONS

This application claims priority under 35 U.S.C. §119 to Japanese Patent Application No. 2009-035514 filed on Feb. 18, 2009, the entire content of which is hereby incorporated by reference.

### BACKGROUND OF THE INVENTION

1. Technical Field

The present invention relates to a data reading circuit that reads data in a nonvolatile memory element from a read terminal.

2. Description of the Related Art

A description is given of a conventional art data reading circuit that reads data in the nonvolatile memory element from the read terminal. FIG. 4 is a diagram illustrating the conventional art data reading circuit.

When a signal φ12 is controlled to be low, a positive channel metal oxide semiconductor (PMOS) transistor 62 turns on. When a nonvolatile memory element 61 turns on by writing data 1 in the nonvolatile memory element 61, the data reading circuit reads data of high level (voltage VPP). Further, when the nonvolatile memory element 61 turns off by writing data 0 in the nonvolatile memory element 61, the data reading circuit reads data of low level (voltage VDD) (for example, refer to JP 2004-294260 A).

However, in the related art, when the nonvolatile memory element 61 turns on, and the data reading circuit reads data of high level (voltage VPP), both of the nonvolatile memory element 61 and the PMOS transistor 62 always turn on, as a result of which a through current flows in the data reading circuit. Hence, a current consumption is increased accordingly.

Further, when, for example, a One Time Program (OTP) element is used as the nonvolatile memory element, a bias is always applied between a source and a drain, a current flows between the source and the drain, and hot electrons are injected into a floating gate. As a result, an absolute value of a threshold voltage of the nonvolatile memory element may be gradually lowered to change data held in the memory element. Further, in the case of using an Electrically Erasable and Programmable Read Only Memory (EEPROM) element, a bias is always applied between a control gate and the drain, and a tunnel current flows between a floating gate and the drain. As a result, there may occur a case in which data is written into the nonvolatile memory element, and the absolute value of the threshold voltage of the nonvolatile memory element 61 is lowered to change data held in the memory element.

### SUMMARY OF THE INVENTION

The present invention has been made in view of the above-mentioned problems, and aims at providing a data reading circuit that is small in the current consumption and is capable of stably holding data.

In order to achieve the above-mentioned problems, the present invention provides a data reading circuit that reads data in a nonvolatile memory element from a read terminal, the data reading circuit including: the nonvolatile memory element that stores the data therein; a first switch disposed between the nonvolatile memory element and the read terminal; a second switch disposed between the read terminal and a second power supply voltage terminal; and a latch circuit that holds the data for a read period during which the data is read.

In the present invention, no through current flows in the data reading circuit during a data read period after the data holding operation of the latch circuit has been completed, and hence the current consumption of the data reading circuit is reduced accordingly. Further, because no voltage is applied to the nonvolatile memory element during a period other than the data holding operation period of the latch circuit, data held in the memory element is stabilized.

### BRIEF DESCRIPTION OF THE DRAWINGS

In the accompanying drawings:

FIG. 1 is a diagram illustrating a data reading circuit according to the present invention;

FIG. 2 is a timing chart illustrating an operation of the data reading circuit according to the present invention;

FIG. 3 is a timing chart illustrating the operation of the data reading circuit according to the present invention; and

FIG. 4 is a diagram illustrating a conventional data reading circuit.

### DETAILED DESCRIPTION OF THE PREFERRED EMBODIMENT

Hereinafter, an embodiment of the present invention is described with reference to the accompanying drawings.

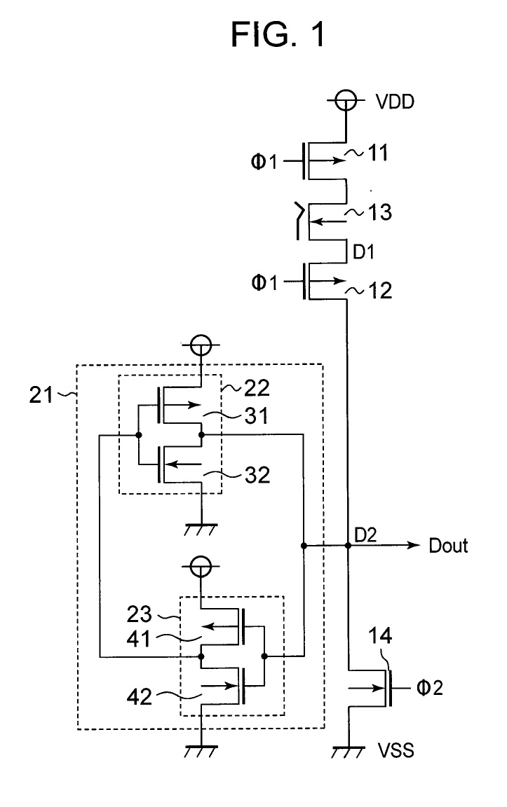

First, a description is given of a configuration of a data reading circuit that reads data in a nonvolatile memory element from a read terminal. FIG. 1 is a diagram illustrating the data reading circuit.

The data reading circuit includes PMOS transistors 11, 12, a nonvolatile memory element 13, a negative channel metal oxide semiconductor (NMOS) transistor 14, and a latch circuit 21. The latch circuit 21 has inverters 22 and 23. The inverter 22 has a PMOS transistor 31 and an NMOS transistor 32. The inverter 23 has a PMOS transistor 41 and an NMOS transistor 42.

The PMOS transistor 11 has a gate to which a signal φ1 is input, a source connected to a power supply terminal, and a drain connected to a source of the nonvolatile memory element 13. The PMOS transistor 12 has a gate to which the signal φ1 is input, a source connected to a drain of the nonvolatile memory element 13, and a drain connected to a read terminal Dout. The NMOS transistor 14 has a gate to which a signal φ2 is input, a source connected to a ground terminal, and a drain connected to the read terminal Dout. The PMOS transistor 31 has a gate connected to an input terminal of the inverter 22, a source connected to the power supply terminal, and a drain connected to an output terminal of the inverter 22. The NMOS transistor 32 has a gate connected to the input terminal of the inverter 22, a source connected to the ground terminal, and a drain connected to the output terminal of the inverter 22. The PMOS transistor 41 has a gate connected to an input terminal of the inverter 23, a source connected to the power supply terminal, and a drain connected to an output terminal of the inverter 23. The NMOS transistor 42 has a gate connected to the input terminal of the inverter 23, a source connected to the ground terminal, and a drain connected to the output terminal of the inverter 23. The input terminal of the inverter 22 and the output terminal of the inverter 23 are connected to each other. The output terminal of the inverter 22 and the input terminal of the inverter 23, and the read terminal are connected to each other.

It is assumed that a voltage of the power supply terminal is a power supply voltage VDD, a voltage of the ground terminal is a ground voltage VSS, a voltage at a connection point between the drain of the nonvolatile memory element 13 and the source of the PMOS transistor 12 is D1, and a voltage of the read terminal (a connection point between the drain of the PMOS transistor 12 and the drain of the NMOS transistor 14) is data D2.

The latch circuit 21 holds the data D2 after having read data in the nonvolatile memory element 13. As the nonvolatile memory element 13, for example, an OTP (One Time Program) element, an EEPROM (Electrically Erasable and Programmable Read Only Memory) element, or a fuse is used, and data is stored therein.

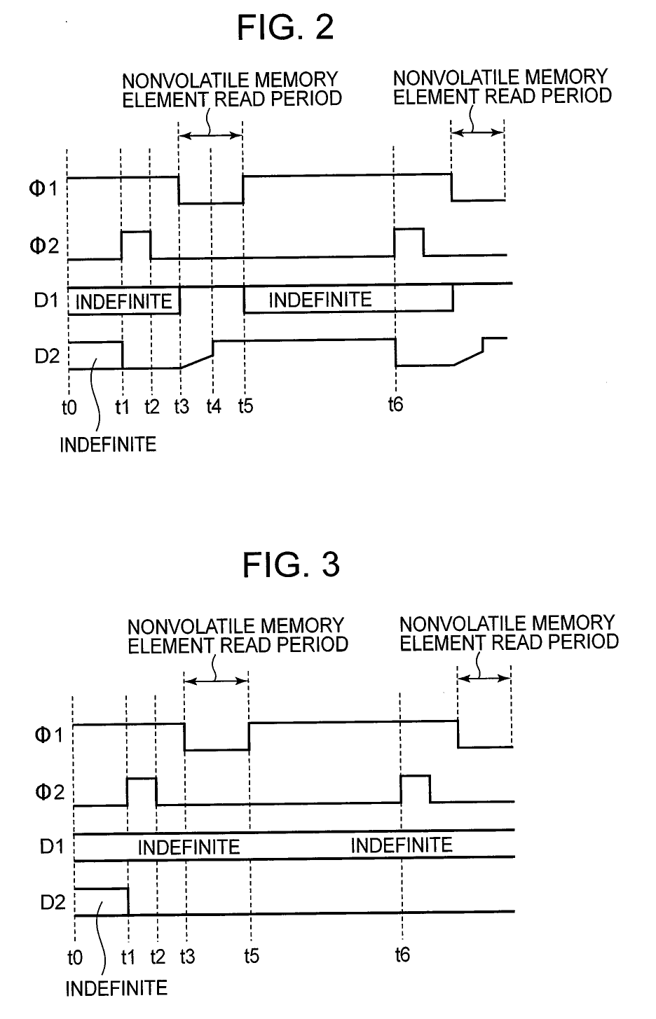

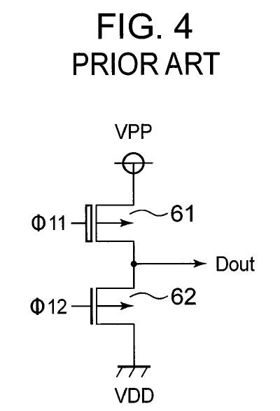

Subsequently, a description is given of an operation of the data reading circuit when data 1 is written in the nonvolatile memory element 13 to render the nonvolatile memory element 13 conductive. FIG. 2 is a timing chart illustrating the operation of the data reading circuit according to the present invention.

When t0≦t<t1, control is made so that the signal φ1 is high, and the signal φ2 is low. As a result, the PMOS transistors 11 and 12, and the NMOS transistor 14 turn off, and hence the data D1 and D2 are indefinite.

During this state, the PMOS transistors 11 and 12 are off, and hence no voltage is applied between a floating gate of the nonvolatile memory element 13 and the source or the drain thereof, and no data is rewritten in the nonvolatile memory element 13.

When t=t1, the signal φ2 is controlled to be high. As a result, the NMOS transistor 14 turns on, and hence the data D2 becomes low. That is, the latch circuit 21 is cleared.

When t=t2, the signal φ2 is controlled to be low. As a result, the NMOS transistor 14 turns off, but the data D2 is held in the latch circuit 21, and hence the data D2 becomes low. In this case, a period during which the signal φ2 is high is set to a period during which the data D2 can be surely made low.

When t=t3 (at the time of starting to read the nonvolatile memory element), the signal φ1 is controlled to be low. As a result, the PMOS transistors 11 and 12 turn on. In this situation, the nonvolatile memory element 13 is rendered conductive, and hence the data D1 becomes high. In this case, the nonvolatile memory element 13 has a drive capability larger than that of the NMOS transistor 32, and hence the data D2 starts to increase.

When t=t4, the data D2 becomes high, and becomes equal to or higher than an inverted voltage of the inverter 23. As a result, the output voltage (input voltage of the inverter 22) of the inverter 23 becomes low, the data D2 becomes high, and a logic held in the latch circuit 21 is inverted. That is, the data holding operation of the latch circuit 21 is completed.

In this example, during the read period of the nonvolatile memory element, the signal φ2 is low, and hence the NMOS transistor 14 is off. As a result, no current flows in the NMOS transistor 14. Further, the data D2 is high, and hence the output voltage of the inverter 23 becomes low, and the NMOS transistor 32 turns off. Hence, no current flows in the NMOS transistor 32. Further, no current flows in the PMOS transistor 31 because the power supply voltage VDD is applied to the source and the drain thereof. As a result, no current flows in the data reading circuit after the data holding operation of the latch circuit 21 has been completed (after time t4), and hence the current consumption of the data reading circuit is reduced accordingly.

When t5≦t<t6 (data read period), the data D2 is latched, and the data D2 can be read from the read terminal Dout. During this period, the PMOS transistors 11 and 12 turn off, and the NMOS transistor 32 also turns off, and hence no through current flows. Further, because no voltage is applied to the nonvolatile memory element 13, there is no change in data that has been written in the nonvolatile memory element 13.

When t≧t6, in the case where the latched data D2 is refreshed, the above-mentioned operation from t1 may be repeated at the time t6.

Subsequently, a description is given of an operation of the data reading circuit when data 0 is written in the nonvolatile memory element 13 to render the nonvolatile memory element 13 nonconductive. FIG. 3 is a timing chart illustrating the operation of the data reading circuit according to the present invention.

At t0≦t≦t2, the operation is identical with the above-mentioned operation.

When t=t3 (at the time of starting to read the nonvolatile memory element), the signal φ1 is controlled to be low. As a result, the PMOS transistors 11 and 12 turn on. However, at this time, the nonvolatile memory element 13 is nonconductive, and hence the data D1 is kept indefinite. In this case, the data D2 is kept low by the NMOS transistor 32 that is on and draws a current from the read terminal.

When t5≦t<t6 (data read period), the data D2 is latched, and the data D2 can be read from the read terminal Dout. During this period, the PMOS transistors 11 and 12 turn off, and the NMOS transistor 32 also turns off, and hence no through current flows. Further, because no voltage is applied to the nonvolatile memory element 13, there is no change in data that has been written in the nonvolatile memory element 13.

When t≧t6, in the case where the latched data is refreshed, the above-mentioned operation from t1 may be repeated at the time t6.

With this arrangement, no current flows in the data reading circuit during the data read period, and hence the current consumption of the data reading circuit is reduced accordingly.

During the data read period, no voltage is applied between the floating gate of the nonvolatile memory element 13 and the source or the drain thereof, and hence no data is rewritten in the nonvolatile memory element 13.

In FIG. 1, there is provided the PMOS transistor 11. Alternatively, it is possible to delete the PMOS transistor 11, and connect the source of the nonvolatile memory element 13 with the power supply terminal according to the specification of the data reading circuit, which is not shown. This configuration is useful particularly in the case where there is a small possibility that data in the nonvolatile memory element 13 is rewritten such as a case in which a current flowing in the nonvolatile memory element 13 is reduced. As a result, there can be obtained an advantage that the current consumption can be reduced, and the circuit scale of the data reading circuit is reduced.

Further, in FIG. 1, the PMOS transistors 11 and 12 and the nonvolatile memory element 13 are disposed between the power supply terminal and the read terminal, and the NMOS transistor 14 is disposed between the read terminal and the ground terminal. Alternatively, a PMOS transistor may be disposed between the power supply terminal and the read terminal, and two NMOS transistors and a nonvolatile memory element may be disposed between the read terminal and the ground terminal, which is not shown.

What is claimed is:

1. A data reading circuit that reads data in a nonvolatile memory element from a read terminal, the data reading circuit comprising:
the nonvolatile memory element that stores the data therein;
a first switch disposed between the nonvolatile memory element and the read terminal;
a second switch disposed between the read terminal and a second power supply voltage terminal; and
a latch circuit that holds the data for a read period during which the data is read.

2. A data reading circuit according to claim 1, further comprising a third switch disposed between a first power supply voltage terminal and the nonvolatile memory element.
